(19) United States
(12) Patent Application Publication
(10) Pub. No.: US 2025/0061618 A1
(43) Pub. Date: Feb. 20, 2025

(54) NOISE-SUPPRESSED NONLINEAR RECONSTRUCTION OF MAGNETIC RESONANCE IMAGES

(71) Applicant: REGENTS OF THE UNIVERSITY OF MINNESOTA, MINNEAPOLIS, MN (US)

(72) Inventors: Steen MOELLER, MINNEAPOLIS, MN (US); Mehmet AKÇAKAYA, MINNEAPOLIS, MN (US); Kamil UGURBIL, MINNEAPOLIS, MN (US)

(21) Appl. No.: 18/720,261

(22) PCT Filed: Dec. 14, 2022
(86) PCT No.: PCT/US2022/052876

§ 371 Date: Jun. 14, 2024

Related U.S. Application Data
(60) Provisional application No. 63/289,526, filed on Dec. 14, 2021.

(51) Int. Cl. G06T 11/00; G01R 33/56; G06T 5/70

(52) U.S. Cl. CPC G06T 11/005; G01R 33/5608; G06T 5/70; G06T 11/006; G06T 2207/10088; G06T 2207/20081; G06T 2207/20084; G06T 2211/441

(57) ABSTRACT

Denoised magnetic resonance images are generated using a two-step process. An initial set of images is first denoised on a per channel basis using a locally low-rank-based denoising technique. The denoised coil channel images are transformed back into k-space and the denoised k-space data are then applied to a nonlinear image reconstruction. In some instances, the nonlinear image reconstruction can be implemented using a trained neural network. The neural network may be trained using a self-supervised learning technique.

### CROSS-REFERENCE TO RELATED APPLICATIONS

This application claims the benefit of U.S. Provisional Patent Application Ser. No. 63/289,526, filed on Dec. 14, 2021, and entitled “NOISE-SUPPRESSED NONLINEAR RECONSTRUCTION OF MAGNETIC RESONANCE IMAGES,” which is herein incorporated by reference in its entirety.

### STATEMENT OF FEDERALLY SPONSORED RESEARCH

This invention was made with government support under HL153146, EB025144, EB027061, and NMI 16978 awarded by the National Institutes of Health, and under CCF-1651825 awarded by the National Science Foundation. The government has certain rights in the invention.

### BACKGROUND

Though functional magnetic resonance imaging (“fMRI”) has revolutionized the understanding of the human brain, higher spatial and temporal resolutions are desirable to study brain function at the mesoscale level. However, these higher resolutions require trade-offs between signal-to-noise ratio (“SNR”), spatio-temporal resolution, and coverage.

Recently, NOise Reduction with Distribution Corrected (“NORDIC”) denoising was proposed to suppress the noise components of image series that cannot be distinguished from thermal noise. NORDIC is applied after parallel imaging reconstruction, which hinders its use in accelerated high spatio-temporal applications, where parallel imaging may suffer from aliasing artifacts.

On the other hand, physics-guided deep learning (“PGDL”) reconstruction has recently gained interest for improving highly-accelerated MRI. Yet, such nonlinear reconstruction does not lead to a well-understood reconstruction noise distribution, which is needed for NORDIC post-processing.

### SUMMARY OF THE DISCLOSURE

The present disclosure addresses the aforementioned drawbacks by providing a method for reconstructing denoised magnetic resonance images. The method includes accessing undersampled k-space data with a computer system, where the undersampled k-space data have been acquired using a multichannel receiver. Coil channel images are reconstructed from the undersampled k-space data using the computer system, where each coil channel image corresponds to a different channel of the multichannel receiver. Denoised coil channel images are then generated with the computer system by applying a denoising algorithm to the coil channel images. Denoised k-space data are generated from the denoised coil channel images using the computer system to transform the denoised coil channel images into k-space. Then, denoised magnetic resonance images are reconstructed from the denoised k-space data using the computer system by applying the denoised k-space data to a nonlinear reconstruction algorithm, generating output as the denoised magnetic resonance images.

It is another aspect of the present disclosure to provide a method for reconstructing denoised magnetic resonance images. In this method, k-space data are accessed with a computer system, where the k-space data have been acquired using a multichannel receiver. Coil channel images are reconstructed from the k-space data using the computer system, where each coil channel image corresponds to a different channel of the multichannel receiver. Denoised coil channel images are then generated with the computer system by applying a singular value thresholding using an LLR model to the coil channel images using the computer system. Denoised k-space data are then generated from the denoised coil channel images using the computer system to transform the denoised coil channel images into k-space. Denoised magnetic resonance images are then reconstructed from the denoised k-space data using the computer system.

The foregoing and other aspects and advantages of the present disclosure will appear from the following description. In the description, reference is made to the accompanying drawings that form a part hereof, and in which there is shown by way of illustration one or more embodiments. These embodiments do not necessarily represent the full scope of the invention, however, and reference is therefore made to the claims and herein for interpreting the scope of the invention.

### BRIEF DESCRIPTION OF THE DRAWINGS

FIG. 1 is a flowchart setting forth the steps of an example method for generating denoised magnetic resonance images using a combined NORDIC denoising and nonlinear image reconstruction, where the NORDIC denoising is applied before the nonlinear image reconstruction is performed.

FIG. 2 illustrates an example workflow for generating denoised coil channel images using a NORDIC denoising process.

FIG. 3 illustrates an example workflow for generating denoised magnetic resonance images using a combined NORDIC denoising and nonlinear image reconstruction.

FIG. 4 is a flowchart setting forth the steps of an example method for training a neural network to reconstruct magnetic resonance images using a nonlinear image reconstruction framework.

FIGS. 5A-5C illustrate examples of noise suppression after parallel image reconstruction (FIG. 5A), rank subadditivity for foldover patches (i.e., aliased image patches) (FIG. 5B) and NORDIC denoising prior to image reconstruction (FIG. 5C).

FIG. 6A shows a representative slice of 0.5 mm isotropic fMRI data with inplane acceleration rate of 3. NORDIC-denoised GRAPPA reduces noise compared to non-denoised GRAPPA, which shows substantial noise amplification. Non-denoised physics-driven DL shows improved image quality compared to non-denoised GRAPPA, but shows loss of details compared to NORDIC-denoised GRAPPA (yellow arrows). NORDIC-denoised physics-driven DL reconstruction shows the highest image quality among all methods preserving the sharpness.

FIG. 6B shows tSNR maps of a slice for all four methods. Non-denoised GRAPPA shows the lowest tSNR. NORDIC-denoised GRAPPA and non-denoised physics-driven DL reconstruction improve upon it substantially, with similar tSNR levels. However, non-denoised physics-driven DL shows anatomical structures, indicative of overregularization. The proposed NORDIC-denoised physics-driven DL reconstruction shows the highest tSNR among all methods, including substantial gains in central brain regions

FIG. 6C shows GLM-derived t-maps for the contrast target using four different reconstructions. Non-denoised GRAPPA is dominated by thermal noise and does not show any meaningful activation. NORDIC-denoised GRAPPA and non-denoised physics-driven DL reveal retinotopically expected extent of activations. NORDIC-denoised physics-driven DL reconstruction (2nd, 2nd column) shows the largest expected extent of activation.

FIG. 7 is a block diagram of an example system for generating denoised magnetic resonance images according to some embodiments described in the present disclosure.

FIG. 8 is a block diagram of example components that can implement the system of FIG. 7.

FIG. 9 is a block diagram of an example MRI system that can implement the methods described in the present disclosure.

### DETAILED DESCRIPTION

Described here are systems and methods for generating magnetic resonance images in which noise is significantly reduced. In general, a noise reduction algorithm such as noise reduction with distribution corrected (“NORDIC”) denoising is combined with a nonlinear image reconstruction, such as a physics-guided deep learning reconstruction (“PGDL”). The combination of the NORDIC denoising with the PGDL reconstruction provides improved denoising and output image quality than using these techniques individually. NORDIC removes Gaussian like noise, and PGDL has better reconstruction accuracy than standard reconstructions. PGDL also has inherent noise suppression capabilities, and balances these against accuracy. By combining NORDIC with PGDL (or other suitable nonlinear reconstruction algorithms) the measured k-space data can be denoised first before an improved reconstruction.

Generally speaking, NORDIC is a framework for parameter-free denoising using locally low rank (“LLR”) processing. For example, LLR principal component analysis with singular value threshold (e.g., hard thresholding) can be used to eliminate signals that cannot be distinguished from thermal noise. In its original implementation, NORDIC denoising is applied after image reconstruction (e.g., after parallel image reconstruction). This renders NORDIC incompatible with nonlinear reconstruction techniques, since nonlinear reconstructions do not result in a well-understood noise distribution that is used in NORDIC post-processing.

The systems and methods described in the present disclosure overcome these drawbacks by applying NORDIC denoising before the nonlinear reconstruction of the data.

In NORDIC denoising, image patches, which may in some implementations include overlapping image patches, are processed. As an example, a patch-based Casorati matrix, Y=[y₁, . . . , y_{τ}, . . . , y_{N}]∈ [symbol] ^{(M×N)} can be constructed, such that each column, y_{τ}, is composed of voxels in a fixed patch, k₁×k₂×k₃, from each volume τ∈{1, . . . , N}. The denoising problem in traditional NORDIC implementations is then to recover the corresponding underlying data Casorati matrix, X, based on the following model:

$$Y = X + N ; \qquad ( 1 )$$

where N∈ [symbol] ^{(M×N)} is additive Gaussian noise. As a non-limiting example, this can be achieved by processing the image series such that the noise component is independently and identically distributed (“i.i.d.”) after reconstruction, and hard thresholding at a level where signals cannot be distinguished from thermal noise (e.g., based on non-asymptotic properties of random matrices). During the NORDIC denoising process, a phase can be calculated from a combination of channels (e.g., using a SENSE 1 combination), and a median filter or other suitable filter can be applied to the phase data in order to smooth the phase data. The smoothed phase can be removed from the combination of channels, from the individual channels, or both. In instances where the original k-space data are fully sampled, this removed phase can be ignored. When the original k-space data are undersampled, the removed phase may be advantageous for the subsequent image reconstruction. Therefore, in those instances the removed phase can be added back after the noise has been removed.

When using a nonlinear reconstruction, the noise is no longer Gaussian, rendering the traditional NORDIC implementation incompatible. The systems and methods described in the present disclosure overcome this drawback by performing NORDIC on the acquired aliased data directly using the same thresholding methodologies. For example, aliased images can be reconstructed on a per coil channel basis, then processed using NORDIC denoising before being transformed back into k-space data prior to nonlinear image reconstruction.

For uniform sampling patterns, where the image patches are aliased onto other patches, this processing amounts to using LLR properties of a sum of Casorati matrices from different patches. Using the subadditivity of matrix rank (i.e., where rank(A+B)≤rank(A)+rank(B)), the aliased image patches will also have LLR properties if the fully sampled image is amenable to LLR processing.

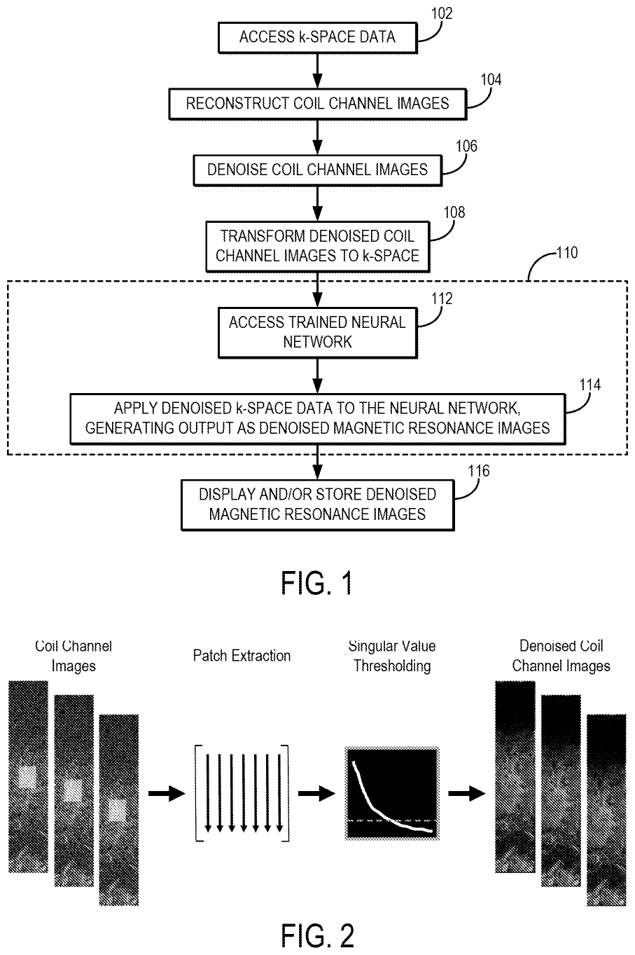

Referring now to FIG. 1, a flowchart is illustrated as setting forth the steps of an example method 100 for reconstructing magnetic resonance images using a suitably trained neural network or other machine learning algorithm. As described below, the method generally includes a combination of denoising an initial set of images on a per coil channel basis, transforming the denoised coil channel images into k-space to create denoised k-space data, and reconstructing denoised magnetic resonance images from the denoised k-space data using a nonlinear image reconstruction, such as PGDL.

The method includes accessing k-space data with a computer system, as indicated at step 102. Accessing the k-space data may include retrieving such data from a memory or other suitable data storage device or medium. Additionally or alternatively, accessing the k-space data may include acquiring such data with an MRI system and transferring or otherwise communicating the data to the computer system, which may be a part of the MRI system.

In general, the k-space data are acquired using a multichannel radio frequency (“RF”) receiver. For example, the k-space data can be acquired using an RF coil array having multiple different receive coils. Additionally or alternatively, the k-space data can be acquired using RF receiver configurations other than a multichannel RF receiver. The k-space data may in any instance be undersampled k-space data.

The k-space data may be indicative of a time series of images. For example, the k-space data may be representative of functional MRI (“fMRI”) data, diffusion-weighted imaging (“DWI”) data, arterial spin labelling (“ASL”) data, or the like.

Coil channel images are then reconstructed from the k-space data using the computer system, as indicated at step 104. The coil channel images correspond to reconstructing an image from the k-space data acquired for different receive channels (e.g., different receive coils in an RF coil array). Although these images may be subject to aliasing artifacts (e.g., in those instances where the k-space data are undersampled), their reconstruction noise distribution can be well-understood and implemented in a NORDIC denoising. For example, the undersampled k-space for each channel can be Fourier-transformed along both the readout and phase-encoding directions in order to reconstruct the coil channel images.

As noted above, in some instances the k-space data, and thus the reconstructed coil channel images, are representative of a time-series of images (i.e., a dynamic series of images), such as in fMRI. Additionally or alternatively, the k-space data, and thus the reconstructed coil channel images, may be representative of a contrast-varying series of images, such as in DWI where different diffusion-weighting contrasts may be implemented.

The images are then denoised using the computer system, as indicated at step 106. The images can be denoised using a denoising algorithm, which may be a channel-independent denoising algorithm or a joint denoising algorithm. As one non-limiting example, the images are denoised using a NORDIC denoising algorithm, or other LLR-based denoising algorithm (e.g., other LLR denoising methods based on random matrix theory), as described above. The thermal noise level can be estimated in each channel (e.g., each coil channel image), such as by estimating the thermal noise level from the edge of the readout.

The LLR PCA part from NORDIC can be used independently for each acquired channel, I_{ch}^{NORDIC,R>1} with a spatial-to-temporal ratio of 11:1, as an example. This results in obtaining new undersampled images that have been denoised:

$${I}_{ch}^{NORDIC , R > 1} = {I}_{ch}^{Acq , R > 1} - N ; \qquad ( 2 )$$

where here N is the estimated complex-valued noise removed using NORDIC.

An example workflow of this denoising process is illustrated in FIG. 2. As described, NORDIC uses overlapping image patches with a ratio (e.g., an 11:1 ratio) between spatial voxels and temporal frames with overlapping patches with a field-of-view (“FOV”) shift between overlapping patches. The FOV shift may be a one-half FOV shift, or other suitable fraction FOV shift (e.g., one-third, one-quarter). A singular value decomposition (“SVD”) can be used for each Casorati matrix, with the threshold calculated as the first singular value from a Casorati matrix of matched dimension with i.i.d. Gaussian entries, and with matched variance to the thermal noise. The first singular value can be estimated from 10 realizations of i.i.d. noise and used for all image patches, as a non-limiting example. Advantageously, g-factor normalization, which is used in traditional NORDIC denoising, is not necessary in these implementations.

Alternatively, other denoising algorithms can be used, including wavelet-based denoising, block-matching and 3D filtering (“BM3D”), block-matching and 4D filtering (“BM4D”), anisotropic denoising, machine learning-based denoising (e.g., a neural network trained to denoise images), other channel-independent denoising algorithms, and so on.

For instance, a neural network can be trained on training data to denoise an input image, and this neural network can be used to generate the denoised coil channel images by inputting the coil channel images to the neural network. The neural network may be a convolutional neural network, or a neural network with another suitable architecture for removing noise from images. In some instances, the neural network can be trained using a self-supervised learning via data undersampling (“SSDU”) strategy, which is described below in more detail. Additionally or alternatively, the neural network can be a pre-trained neural network that is fine-tune in a scan-specific (i.e., subject-specific) manner using k-space data or images acquired from the same subject as the k-space data accessed in step 102. Based on the SSDU techniques described below in more detail, a pre-trained network can be fine-tuned (e.g., on a per-scan or scan-specific basis) using the following loss function for the fine-tuning phase:

$${min}_{θ} L ( {y}_{Λ} , {E}_{Λ} ( f ( {y}_{Θ} , {E}_{Θ} ; θ ) ) ) ; \qquad ( 3 )$$

where E_{A} transforms the network output image into the k-space domain (e.g., the coil k-space domain), so the loss can be defined with respect to the k-space points y_{A}. The network parameters θ can be initialized with database-trained network values. These parameters are then fine-tuned, using only the same data that are to be denoised, such that the fine tuning of the network is performed on a per-scan or scan-specific basis. Thus, y_{Θ} is used as the data input to the neural network, whose parameters are tuned to best estimate y_{A} at the output based on the loss function. During the final reconstruction, the complete set of measurement data y_{Ω} is then input into the finely-tuned network.

The denoised coil channel images are then transformed back into k-space, generating denoised k-space data, as indicated at step 108. For example, an inverse Fourier transform can be applied to the denoised coil channel images to transform the images into the denoised k-space data.

In some other implementations, the denoised k-space data can be generated by performing denoising directly on the k-space data accessed in step 102, rather than on coil channel images, or other images, reconstructed from the k-space data. In these instances, steps 104-106 can be replaced with a single step of denoising the k-space data using a suitable denoising algorithm. As one non-limiting example, the LLR-based denoising techniques described above can be adapted to be applied in an adjunct and/or transform space (e.g., k-space). For instance, the k-space data can be denoised using an LLR model that assume the data matrix for a given patch is low-rank, and performing singular value thresholding on the noisy data matrix to eliminate unwanted noise components. As an example, the noisy data, Y=X+N described above can be represented in k-space rather than the image domain. The singular value decomposition of Y can be represented as USV^{H}, where S is a diagonal matrix whose entries are the spectrum of ordered singular values sⱼ∈{1, . . . , min(M,T)}. For a thresholding value of 2, a soft-thresholded or hard-thresholded matrix, S_{λ} is used to form the denoised matrix as US_{λ}V^{H}. The denoised k-space data can then be obtained by extracting patches from the denoised matrices, and optionally performing patch averaging to account for overlaps between patches. As described above, LLR approaches can use random matrix theory formulations to automatically determine the threshold, λ. As an example, these methods perform a number of processing steps to ensure that N has independent identically distributed (i.i.d.) entries. Subsequently, the threshold is determined by either asymptotic properties, such as the Marchenko-Pastur distribution on the singular values of N, using non-asymptotic variants, or the like.

Images are then reconstructed, or otherwise generated, from the denoised k-space data, as indicated at process block 110. As one non-limiting example, the images can be generated by inputting the denoised k-space data to a neural network or other machine learning algorithm or model, as described below in more detail. Alternatively, the images can be reconstructed from the denoised k-space data using other non-linear or linear reconstruction algorithms.

As mentioned, in one non-limiting example, a trained neural network (or other suitable machine learning algorithm or model) is then accessed with the computer system, as indicated at step 112. As described above, the neural network can be trained to implement a PGDL-based image reconstruction. In other instances, the neural network can be trained to implement other nonlinear image reconstructions. In still other instances, the neural network may not be implemented and instead the denoised k-space data can be applied directly to a nonlinear or linear image reconstruction implemented without the use of machine learning.

Accessing the trained neural network may include accessing network parameters (e.g., weights, biases, or both) that have been optimized or otherwise estimated by training the neural network on training data. In some instances, accessing the neural network can also include retrieving, constructing, or otherwise accessing the particular neural network architecture to be implemented. For instance, data pertaining to the layers in the neural network architecture (e.g., number of layers, type of layers, ordering of layers, connections between layers, hyperparameters for layers) may be retrieved, selected, constructed, or otherwise accessed.

In general, the neural network is trained, or has been trained, on training data in order to reconstruct magnetic resonance images from k-space data using a physics-guided or other nonlinear reconstruction framework.

The denoised k-space data are then input to the trained neural network or other machine learning model, generating output as magnetic resonance images that have been denoised, as indicated at step 114. For example, a PGDL reconstruction such as the following can be used:

$$arg {min}_{x} {‖ {y}_{Ω} - {E}_{Ω} x ‖}_{2}^{2} + R ( x ) ; \qquad ( 4 )$$

where y is the denoised k-space data with undersampling pattern, Ω; x is the image being reconstructed; E_{Ω} is the multi-coil encoding operator; and R( . . . ) is a regularizer. As a non-limiting example, this objective function can be solved using variable splitting with a quadratic penalty that splits the optimization problem in into two sub-problems:

$${z}^{( l - 1 )} = arg {min}_{z} μ {‖ {x}^{( l - 1 )} - z ‖}_{2}^{2} + R ( z ) ; \qquad ( 5 )$$

$${x}^{( l )} = arg {min}_{x} {‖ {y}_{Ω} - {E}_{Ω} x ‖}_{2}^{2} + μ {‖ x - {z}^{( l - 1 )} ‖}_{2}^{2} ; \qquad ( 6 )$$

where x^{(l)} is the reconstructed image at the lth iteration, z^{(l)} is an auxiliary image, and μ is the quadratic penalty parameter.

In some implementations, PGDL reconstruction alternates between Eqns. (5) and (6) for a fixed number of iterations in a process called algorithm unrolling. Algorithm unrolling can be used to solve the objective function, leading to a data consistency (“DC”) and regularization sub-problem at each unroll. In these instances, conventional supervised training may not be adequate due to the lack of fully-sampled training data at such high resolutions. Thus, self-supervised learning via data undersampling (“SSDU”) strategy can be used, which splits Ω into two disjoints sets, where one is used in DC units and the other to define k-space loss. For instance, the unrolled network can be trained end-to-end using a loss function with respect to a reference image, such as the following loss function, which may be used for supervised training:

$${min}_{θ} \frac{1}{N} {\sum }_{n = 1}^{N} L ( {x}_{ref , n} , f ( {y}_{Ω , n} , {E}_{Ω , n} ; θ ) ) ; \qquad ( 7 )$$

where f(y_{Ω,n},E_{Ω,n};θ) is the output of the unrolled network parametrized by θ, N is the number of training datasets in the database, L(⋅,⋅) is a loss function, x_{ref,n} is the reference image for the nth training sample, y_{Ω,n} are the acquired k-space data for the nth training sample, and E_{Ω,n} is the multi-coil encoding operator for the nth training sample.

In those instances where the nonlinear image reconstruction is implemented without a neural network or other machine learning algorithm, the denoised k-space data are applied directly to that nonlinear reconstruction algorithm, generating output as the denoised magnetic resonance images. In still other example implementations, the denoising can be performed prior to using other reconstruction techniques or algorithms, including linear reconstruction algorithms.

The reconstructed magnetic resonance images can then be displayed to a user, stored for later use or further processing, or both, as indicated at step 116. For instance, the images generated by inputting the denoised k-space data to the trained neural network(s) (or other machine learning model(s)) can be displayed to a user, stored for later use or further processing, or both. Alternatively, images reconstructed from the denoised k-space data using other reconstruction techniques (e.g., other non-linear reconstruction algorithms, linear reconstruction algorithms, and so on) can be displayed to a user, stored for later use or further processing, or both.

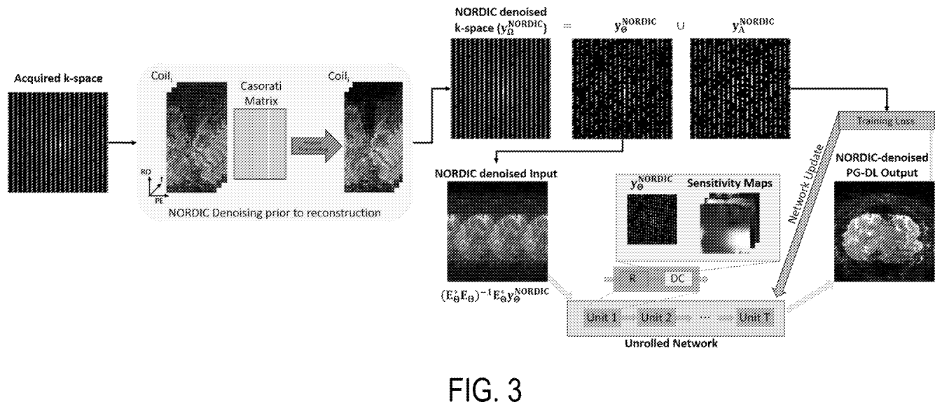

Referring to FIG. 3, an example workflow for the combination of NORDIC denoising on acquired k-space data and self-supervised PGDL reconstruction is illustrated. As described above, NORDIC denoising is performed on aliased images from individual channels of acquired k-space. Algorithm unrolling is used with data consistency and regularizer units of the PGDL network. For self-supervised training without fully-sampled data, the NORDIC-denoised k-space data are split into two disjoint sets, where one is used in DC units and the other to define training loss.

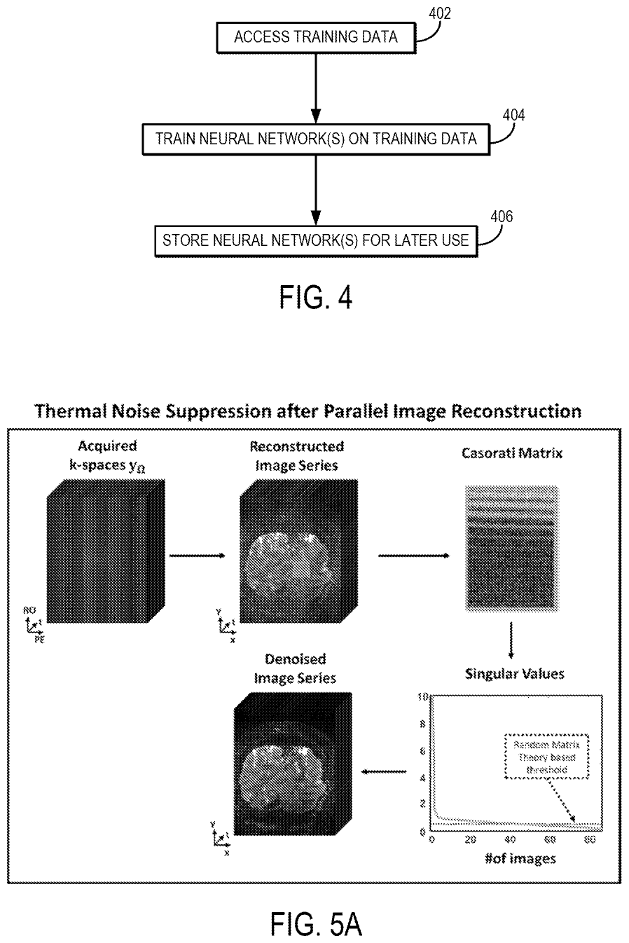

Referring now to FIG. 4, a flowchart is illustrated as setting forth the steps of an example method for training one or more neural networks (or other suitable machine learning algorithms) on training data, such that the one or more neural networks are trained to receive input(s) as k-space data in order to generate output(s) as reconstructed magnetic resonance images.

In general, the neural network(s) can implement any number of different neural network architectures. For instance, the neural network(s) could implement a convolutional neural network, a residual neural network, and the like.

Alternatively, the neural network(s) could be replaced with other suitable machine learning algorithms, such as those based on supervised learning, self-supervised learning, unsupervised learning, deep learning, ensemble learning, dimensionality reduction, and so on.

The method includes accessing training data with a computer system, as indicated at step 402. Accessing the training data may include retrieving such data from a memory or other suitable data storage device or medium. Additionally or alternatively, accessing the training data may include acquiring such data with an MRI system and transferring or otherwise communicating the data to the computer system, which may be a part of the MRI system.

In general, the training data can include k-space data, such as undersampled k-space data. Additionally or alternatively, the training data can include fully sampled k-space data. When the training data include undersampled k-space data, it can be advantageous to use self-supervised learning techniques, such as those described in the present disclosure. When the training data include fully sampled k-space data, it can be advantageous to use supervised learning techniques.

In some embodiments, accessing the training data may include assembling training data from k-space using the computer system. This step may include assembling the k-space data into an appropriate data structure on which the neural network or other machine learning algorithm can be trained. Assembling the training data may include assembling k-space data, segmented k-space data, and other relevant data. For instance, assembling the training data may include separating the training data into two disjoint subsets for self-supervised learning: one set, Θ, used in DC units and the other set, A, to define k-space loss. Alternatively, the assembling the training data may include separating the data into three disjoint subsets for self-supervised learning: one set, Θ, used in DC units, one set, Θ, to define k-space loss, and one set, Γ, to establish an early stopping criterion.

In some embodiments, accessing the training data may also include augmenting the training data, such as by generating cloned data from the k-space data. As an example, the cloned data can be generated by making copies of the k-space data while altering or modifying each copy of the k-space data. For instance, cloned data can be generated using data augmentation techniques, such as adding noise to the original k-space data, performing a deformable transformation (e.g., translation, rotation, both) on the original k-space data, smoothing the original k-space data, applying a random geometric perturbation to the original k-space data, combinations thereof, and so on. The cloned data can then be included as part of the training data.

One or more neural networks (or other suitable machine learning algorithms) are trained on the training data, as indicated at step 404. In general, the neural network(s) can be trained by optimizing network parameters (e.g., weights, biases, or both) based on minimizing a loss function. As described above, the machine learning algorithm can be trained on the training data using, in part, a loss function that implements the separate subset of loss criterion data.

As one example, training a neural network may include initializing the neural network, such as by computing, estimating, or otherwise selecting initial network parameters (e.g., weights, biases, or both). Training data can then be input to the initialized neural network, generating output as output data, which in the context of an image reconstruction technique can include one or more reconstructed images. The quality of the output data can then be evaluated, such as by passing the output data to the loss function to compute an error. The current neural network can then be updated based on the calculated error (e.g., using backpropagation methods based on the calculated error). For instance, the current neural network can be updated by updating the network parameters (e.g., weights, biases, or both) in order to minimize the loss according to the loss function. When the error has been minimized (e.g., by determining whether an error threshold or other stopping criterion has been satisfied), the current neural network and its associated network parameters represent the trained neural network.

The one or more trained neural networks are then stored for later use, as indicated at step 406. Storing the neural network(s) may include storing network parameters (e.g., weights, biases, or both), which have been computed or otherwise estimated by training the neural network(s) on the training data. Storing the trained neural network(s) may also include storing the particular neural network architecture to be implemented. For instance, data pertaining to the layers in the neural network architecture (e.g., number of layers, type of layers, ordering of layers, connections between layers, hyperparameters for layers) may be stored.

In some implementations, multiple masks can be used in order to further improve the reconstruction performance of the self-supervised learning via data undersampling (“SSDU”) systems and methods described in the present disclosure. SSDU reconstruction quality may degrade at very high acceleration rates due to higher data scarcity, arising from the splitting of Ω into Θ and Λ. The multi-mask implementation of SSDU addresses these situations by splitting the acquired measurements, Ω, into multiple pairs of disjoint sets for each training slice, while using one of these sets for DC units and the other for defining loss, similar to the SSDU techniques described above. The multi-mask SSDU approach can significantly improve upon SSDU performance at high acceleration rates, in addition to providing SNR improvement and aliasing artifact reduction relative to other deep learning-based MRI reconstruction techniques.

As a non-limiting example of the aforementioned process, when the data are acquired with uniformly undersampled patterns, as in fMRI with echo planar imaging (“EPI”), the aliasing artifact is a foldover artifact, in which R pixels of the full field-of-view image are folded onto each other in this aliased field-of-view, where R is the acceleration rate. The effect is similar on patches in the image, where a patch in the undersampled image with foldover artifacts corresponds to the summation of R patches from the full field-of-view image. Repeating the process across the fMRI time series, and noting the subadditivity of matrix rank mentioned above, the Casorati matrices for the patches in the undersampled images are likely to be low-rank when the Casorati matrices corresponding to the patches in the full field-of-view image are sufficiently low-rank.

Because the aliasing artifacts occur independently in each receiver coil, the data from each coil can be processed individually, where the acquisition noise is i.i.d. in nature. Thus, the acquired undersampled k-space for a given coil is first converted to the image domain (i.e., reconstructing the coil channel images), albeit with the foldover aliasing artifacts. Then, image patches from different time-frames in the fMRI image series can be extracted, vectorized, and concatenated to form noisy and aliased Casorati matrices. This is followed by singular value thresholding, using an LLR model based on the subadditivity of the matrix rank. Here, the threshold can be chosen based on a random matrix theory characterization. This is followed by patch averaging to generate the denoised folded-over images for each time-series for the given coil. Finally, these images are taken back to undersampled k-space for each coil.

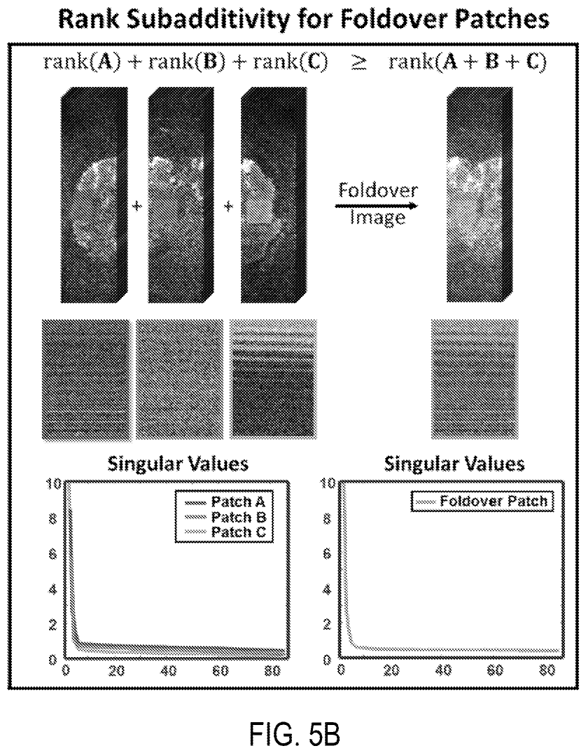

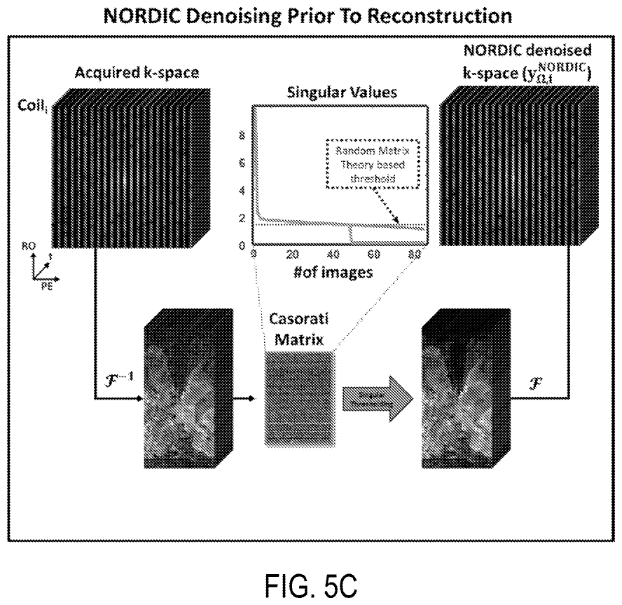

FIGS. 5A-5C illustrate an example of this process. FIG. 5A illustrates noise suppression after image reconstruction with an LLR model and random matrix theory based threshold, which is the conventional paradigm. Local patches are extracted from reconstructed images to form Casorati matrices. Singular value thresholding is performed using a random matrix theory based threshold that removes unwanted noise components. Lastly, patch averaging is performed to form the denoised image series. FIG. 5B shows an example of rank subadditivity of the Casorati matrices at an acceleration rate of R=3. When uniform undersampling is performed, the small patches fold onto other patches preserving LLR properties. FIG. 5C shows an example of NORIDC denoising performed on aliased images from individual channels of acquired k-space prior to reconstruction.

The denoised k-space data are then used to train a physics-driven reconstruction neural network (e.g., a PGDL network). When fully-sampled reference data are not available, a supervised training strategy will not be applicable. In these instances, unsupervised strategies that allow training without fully-sampled data can be used. As noted above, a self-supervised learning technique can be used, such as SSDU, which splits the acquired k-space locations, Ω, into two disjoint sets: Θ and Λ. As noted above, the first set, Θ, can be used in the DC units, while the second set, Λ, remains unseen by the network and can be used to define the k-space training loss. To further improve the performance, multiple disjoint pairs of (Θₖ, Λₖ), k∈{1, . . . , K}can be used in a multi-mask version of SSDU. This leads to following training loss:

$${min}_{θ} \frac{1}{N \cdot K} {\sum }_{n = 1}^{N} {\sum }_{k = 1}^{K} L ( {y}_{{Λ}_{k , n}} , {E}_{{Λ}_{k , n}} ( f ( {y}_{{Θ}_{k , n}} , {E}_{{Θ}_{k , n}} ; θ ) ) ) ; \qquad ( 8 )$$

where N is the number of training data in the database, L (⋅,⋅) is the loss function, and Θ_{k,n} and Λ_{k,n} are the kth DC and loss masks for the nth training data sample, respectively.

In an example study, imaging experiments were performed at 7T in three subjects using a 32-channel head coil. A T2*-weighted 3D GE-EPI sequence was performed, which covered 40 slices with TR=83 ms (Volume Acquisition Time=3654 ms with 10% slice oversampling). The relevant imaging parameters were: TE=32.4 ms, flip angle=13 degrees, bandwidth=820 Hz, phase-encoding acceleration R=3, partial-Fourier=6/8, 0.5 mm isotropic resolution. In total, eight runs were acquired each lasting around five and a half minutes. All runs were collected with a standard 24s on, 24s off visual block design paradigm with a center/target and surrounded checkerboard counter phase flickering at 6 Hz.

NORDIC denoising was applied on the undersampled 3D-EPI images as described above. After read-out over-sampling was removed, eddy current and timing correction were applied. Then, an inverse Fourier transform was applied along each of the three k-space dimensions for each channel individually. A 3D spatial patch, with a spatial:temporal ratio of 11:1 was used. For an acquisition with T≈90, this corresponds to 10×10×10 patches in the images with foldover along the phase-encoding direction. These were used to form the Casorati matrices for LLR modeling. For each channel, the thermal noise level was determined from the readout direction using the standard deviation of all the signals with the highest and lowest frequency. Using the standard deviation of the thermal noise, a matrix with i.i.d. entries of identical dimension to the Casorati matrix and identical standard deviation to the thermal noise was generated. From the i.i.d. generated matrix, the sample mean for the highest singular value was determined, and used as the threshold for singular value thresholding on the noisy Casorati matrices.

Following denoising, a physics-driven deep learning re-construction network was trained with multi-mask SSDU using K=3 masks. First, the 3D-EPI k-space was inverse Fourier transformed along the slice direction, and these slices were processed individually leading to reduced memory requirements. The physics-driven deep learning was unrolled for 10 iterations alternating between the regularizer and the DC sub-problems in Eqns. (5) and (6). The latter was solved using conjugate gradient, which itself was unrolled for 10 iterations. The proximal operator for the regularizer in Eqn. (5) was solved by a convolutional neural network based on a ResNet structure. Sensitivity maps were estimated using ESPIRiT from a low resolution scan, and were used in DC units. A normalized [symbol] ₁− [symbol] ₂ loss was used for L(⋅,⋅). Adam optimizer with a learning rate of 3×10⁻⁴ was used over 100 epochs. Training was performed using a total number of 352 2D k-spaces from two subjects, each having four runs and 44 slices with one time-frame per subject. Testing was performed on a different subject unseen by the network, where all runs, all slices, and all time-frames were reconstructed. During the deep learning reconstruction, each time-frame was reconstructed individually, thus no temporal information was shared across image series.

Comparisons were made between four methods: Conventional parallel imaging, using GRAPPA, performed on acquired (non-denoised) raw k-space, referred to as “Non-denoised GRAPPA”; NORDIC denoising applied to k-space prior to GRAPPA reconstruction, referred to as “NORDIC-denoised GRAPPA”; physics-driven deep learning reconstruction performed on acquired (non-denoised) raw k-space, referred to as “Non-denoised Physics-Driven (PD) DL”; and the proposed method, where physics-driven deep learning reconstruction was performed on the NORDIC-denoised raw k-space, referred to as “NORDIC-denoised Physics-Driven (PD) DL.” GRAPPA kernels were calibrated using 5×4 kernel size for in-plane unaliasing, using the same calibration data utilized for the generation of the ESPIRiT coil maps for physics-driven deep learning. Separate trainings for non-denoised and NORDIC-denoised raw k-spaces were performed for deep learning reconstruction using the same setup.

Functional pre-processing was performed in BrainVoyager. First, 3D rigid body motion correction was applied, where for each run, each volume was realigned to the first volume of the first run using sinc interpolation. Additionally, de-trending was performed by regressing out low-drifts, up to third-order discrete cosine transform from the motion corrected time series. Subsequently, standard general linear model (“GLM”) with ordinary least squares minimization was performed to estimate BOLD-evoked response amplitudes. GLM design matrices were generated by convolving of a double gamma with a “box car” function, the latter representing the stimuli's onsets and offsets. GLM analyses were performed on all runs concatenated for each reconstruction independently. For each voxel, percent signal change amplitudes were computed by dividing the GLM beta weights (representing BOLD evoked responses) by the mean of the pre-processed time series. Temporal SNR (“tSNR”) was computed on a pixel basis, by dividing the mean of the pre-processed time courses by their standard deviations.

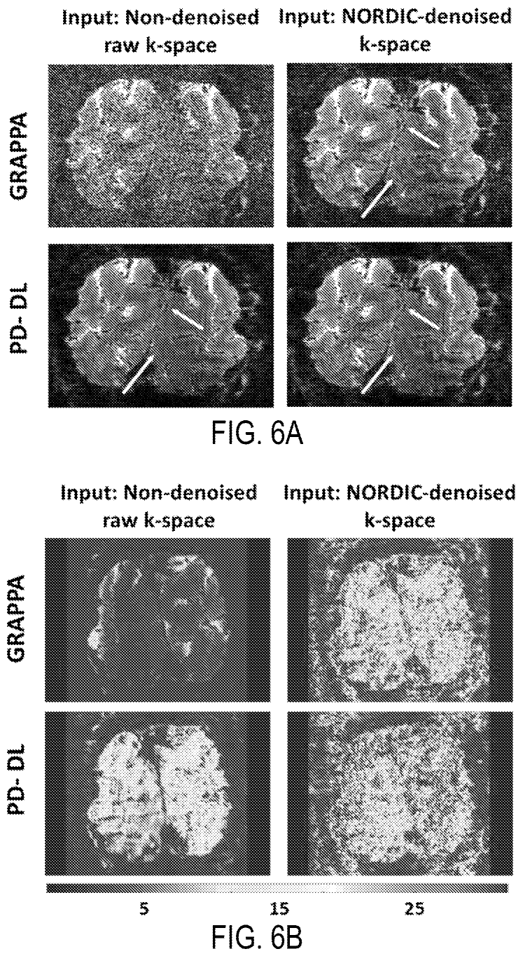

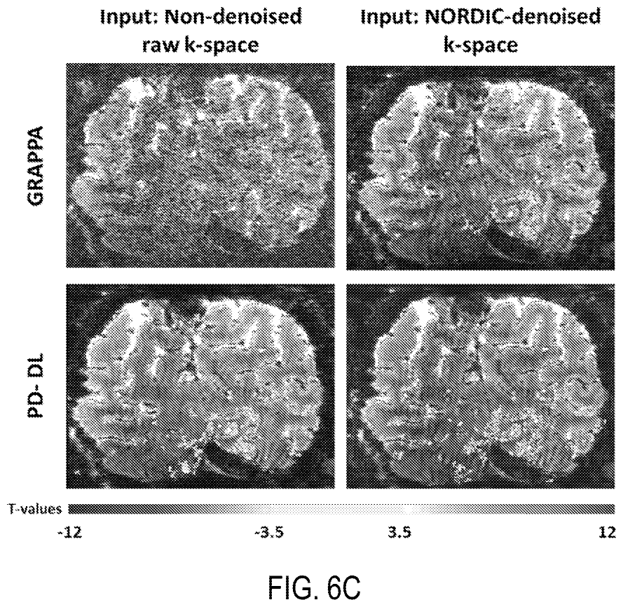

Representative reconstructed slices are shown in FIG. 6. Among all methods, non-denoised GRAPPA showed substantial amount of noise amplification rendering unusable image quality. NORDIC-denoised GRAPPA (1st row, 2nd column) and non-denoised physics-driven DL (2nd row, 1st column) both reduce the noise compared to non-denoised GRAPPA. Note some loss of details were seen in non-denoised physics-driven DL reconstruction shown by yellow arrows, indicative of spatial smoothing. The proposed NORDIC-denoised physics-driven DL reconstruction (2nd, 2nd column) shows visually the best image quality with reduced noise and preservation of fine details.

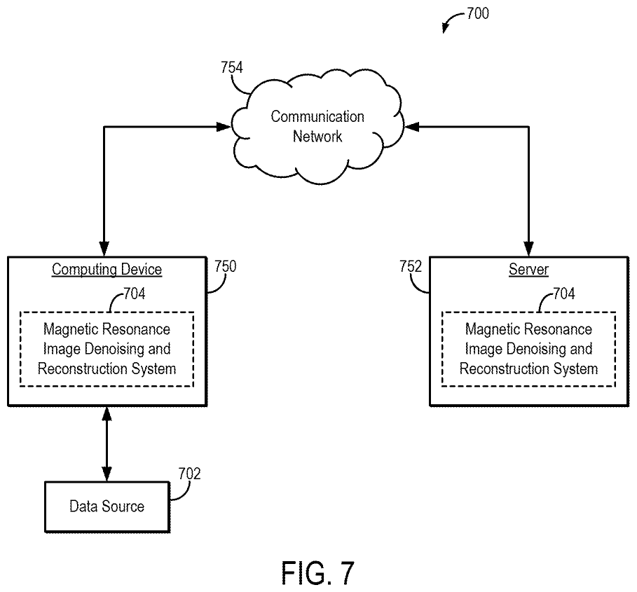

tSNR maps are depicted in FIG. 7 for all methods. Non-denoised GRAPPA shows the lowest tSNR among all methods, while NORDIC-denoised GRAPPA substantially improved upon it. Although tSNR gain was also seen in the non-denoised physics-driven DL, there is lower tSNR in brain periphery regions compared to NORDIC-denoised GRAPPA. Additionally, these tSNR maps show anatomical structures, indicative of over-regularization in the non-denoised physics-driven DL. The proposed NORDIC-denoised physics-driven DL reconstruction shows the highest tSNR gain among all including gains in the central brain regions, with no discernible over-regularization.

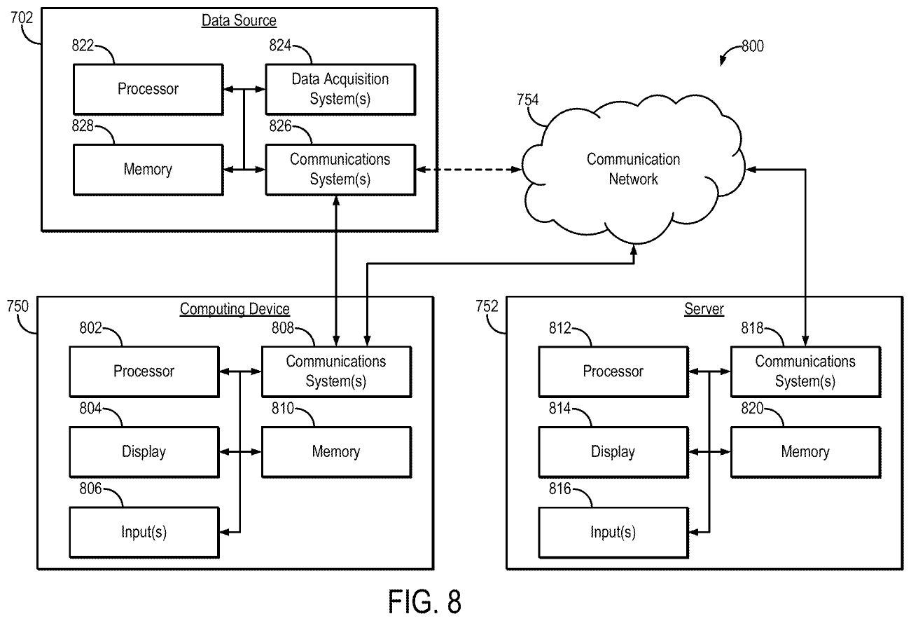

FIG. 8 shows GLM-derived t-maps for the contrast target and surround >0 for all reconstructions. Non-denoised GRAPPA t-maps are dominated by thermal noise, leading to no meaningful activation. NORDIC-denoised GRAPPA and non-denoised physics-driven DL allow retrieval of the retinotopically expected extent of activation. The NORDIC-denoised physics-driven DL leads to the largest expected extent of activation.

This example illustrates that the systems and methods described in the present disclosure provide a new computational imaging pipeline for high-resolution fMRI to enable target voxel volumes of ≤0.1 μL. By redesigning the standard pipeline of image reconstruction followed by denoising, the disclosed systems and methods enable a synergistic combination of fMRI denoising methods based on LLR modeling and random matrix theory with physics-driven deep learning reconstruction. The proposed processing can outperform physics-driven deep learning or NORDIC denoising alone, both visually, and in terms of tSNR and GLM-derived t-maps, enabling high-quality 0.5 mm isotropic resolution fMRI.

Referring now to FIG. 7, an example of a system 700 for generating denoised images in accordance with some embodiments of the systems and methods described in the present disclosure is shown. As shown in FIG. 7, a computing device 750 can receive one or more types of data (e.g., k-space data, training data) from data source 702, which may be a k-space data source. In some embodiments, computing device 750 can execute at least a portion of a magnetic resonance image denoising and reconstruction system 704 to reconstruct denoised magnetic resonance images from k-space data received from the data source 702.

Additionally or alternatively, in some embodiments, the computing device 750 can communicate information about data received from the image source 702 to a server 752 over a communication network 754, which can execute at least a portion of the magnetic resonance image denoising and reconstruction system 704. In such embodiments, the server 752 can return information to the computing device 750 (and/or any other suitable computing device) indicative of an output of the magnetic resonance image denoising and reconstruction.

In some embodiments, computing device 750 and/or server 752 can be any suitable computing device or combination of devices, such as a desktop computer, a laptop computer, a smartphone, a tablet computer, a wearable computer, a server computer, a virtual machine being executed by a physical computing device, and so on. The computing device 750 and/or server 752 can also reconstruct images from the data.

In some embodiments, data source 702 can be any suitable source of data (e.g., measurement data, images reconstructed from measurement data), such as an MRI system, another computing device (e.g., a server storing k-space data), and so on. In some embodiments, data source 702 can be local to computing device 750. For example, data source 702 can be incorporated with computing device 750 (e.g., computing device 750 can be configured as part of a device for measuring, recording, estimating, acquiring, or otherwise collecting or storing data). As another example, data source 702 can be connected to computing device 750 by a cable, a direct wireless link, and so on. Additionally or alternatively, in some embodiments, data source 702 can be located locally and/or remotely from computing device 750, and can communicate data to computing device 750 (and/or server 752) via a communication network (e.g., communication network 754).

In some embodiments, communication network 754 can be any suitable communication network or combination of communication networks. For example, communication network 754 can include a Wi-Fi network (which can include one or more wireless routers, one or more switches, etc.), a peer-to-peer network (e.g., a Bluetooth network), a cellular network (e.g., a 3G network, a 4G network, etc., complying with any suitable standard, such as CDMA, GSM, LTE, LTE Advanced, WiMAX, etc.), other types of wireless network, a wired network, and so on. In some embodiments, communication network 754 can be a local area network, a wide area network, a public network (e.g., the Internet), a private or semi-private network (e.g., a corporate or university intranet), any other suitable type of network, or any suitable combination of networks. Communications links shown in FIG. 7 can each be any suitable communications link or combination of communications links, such as wired links, fiber optic links, Wi-Fi links, Bluetooth links, cellular links, and so on.

Referring now to FIG. 8, an example of hardware 800 that can be used to implement data source 702, computing device 750, and server 752 in accordance with some embodiments of the systems and methods described in the present disclosure is shown.

As shown in FIG. 8, in some embodiments, computing device 750 can include a processor 802, a display 804, one or more inputs 806, one or more communication systems 808, and/or memory 810. In some embodiments, processor 802 can be any suitable hardware processor or combination of processors, such as a central processing unit (“CPU”), a graphics processing unit (“GPU”), and so on. In some embodiments, display 804 can include any suitable display devices, such as a liquid crystal display (“LCD”) screen, a light-emitting diode (“LED”) display, an organic LED (“OLED”) display, an electrophoretic display (e.g., an “e-ink” display), a computer monitor, a touchscreen, a television, and so on. In some embodiments, inputs 806 can include any suitable input devices and/or sensors that can be used to receive user input, such as a keyboard, a mouse, a touchscreen, a microphone, and so on.

In some embodiments, communications systems 808 can include any suitable hardware, firmware, and/or software for communicating information over communication network 754 and/or any other suitable communication networks. For example, communications systems 808 can include one or more transceivers, one or more communication chips and/or chip sets, and so on. In a more particular example, communications systems 808 can include hardware, firmware, and/or software that can be used to establish a Wi-Fi connection, a Bluetooth connection, a cellular connection, an Ethernet connection, and so on.

In some embodiments, memory 810 can include any suitable storage device or devices that can be used to store instructions, values, data, or the like, that can be used, for example, by processor 802 to present content using display 804, to communicate with server 752 via communications system(s) 808, and so on. Memory 810 can include any suitable volatile memory, non-volatile memory, storage, or any suitable combination thereof. For example, memory 810 can include random-access memory (“RAM”), read-only memory (“ROM”), electrically programmable ROM (“EPROM”), electrically erasable ROM (“EEPROM”), other forms of volatile memory, other forms of non-volatile memory, one or more forms of semi-volatile memory, one or more flash drives, one or more hard disks, one or more solid state drives, one or more optical drives, and so on. In some embodiments, memory 810 can have encoded thereon, or otherwise stored therein, a computer program for controlling operation of computing device 750. In such embodiments, processor 802 can execute at least a portion of the computer program to present content (e.g., images, user interfaces, graphics, tables), receive content from server 752, transmit information to server 752, and so on. For example, the processor 802 and the memory 810 can be configured to perform the methods described herein (e.g., the method 100 of FIG. 1; the method 400 of FIG. 4).

In some embodiments, server 752 can include a processor 812, a display 814, one or more inputs 816, one or more communications systems 818, and/or memory 820. In some embodiments, processor 812 can be any suitable hardware processor or combination of processors, such as a CPU, a GPU, and so on. In some embodiments, display 814 can include any suitable display devices, such as an LCD screen, LED display, OLED display, electrophoretic display, a computer monitor, a touchscreen, a television, and so on. In some embodiments, inputs 816 can include any suitable input devices and/or sensors that can be used to receive user input, such as a keyboard, a mouse, a touchscreen, a microphone, and so on.

In some embodiments, communications systems 818 can include any suitable hardware, firmware, and/or software for communicating information over communication network 754 and/or any other suitable communication networks. For example, communications systems 818 can include one or more transceivers, one or more communication chips and/or chip sets, and so on. In a more particular example, communications systems 818 can include hardware, firmware, and/or software that can be used to establish a Wi-Fi connection, a Bluetooth connection, a cellular connection, an Ethernet connection, and so on.

In some embodiments, memory 820 can include any suitable storage device or devices that can be used to store instructions, values, data, or the like, that can be used, for example, by processor 812 to present content using display 814, to communicate with one or more computing devices 750, and so on. Memory 820 can include any suitable volatile memory, non-volatile memory, storage, or any suitable combination thereof. For example, memory 820 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some embodiments, memory 820 can have encoded thereon a server program for controlling operation of server 752. In such embodiments, processor 812 can execute at least a portion of the server program to transmit information and/or content (e.g., data, images, a user interface) to one or more computing devices 750, receive information and/or content from one or more computing devices 750, receive instructions from one or more devices (e.g., a personal computer, a laptop computer, a tablet computer, a smartphone), and so on.

In some embodiments, the server 752 is configured to perform the methods described in the present disclosure. For example, the processor 812 and memory 820 can be configured to perform the methods described herein (e.g., the method 100 of FIG. 1; the method 400 of FIG. 4).

In some embodiments, data source 702 can include a processor 822, one or more data acquisition systems 824, one or more communications systems 826, and/or memory 828. In some embodiments, processor 822 can be any suitable hardware processor or combination of processors, such as a CPU, a GPU, and so on. In some embodiments, the one or more data acquisition systems 824 are generally configured to acquire data, images, or both, and can include an MRI system. Additionally or alternatively, in some embodiments, the one or more data acquisition systems 824 can include any suitable hardware, firmware, and/or software for coupling to and/or controlling operations of an MRI system. In some embodiments, one or more portions of the data acquisition system(s) 824 can be removable and/or replaceable.

Note that, although not shown, data source 702 can include any suitable inputs and/or outputs. For example, data source 702 can include input devices and/or sensors that can be used to receive user input, such as a keyboard, a mouse, a touchscreen, a microphone, a trackpad, a trackball, and so on. As another example, data source 702 can include any suitable display devices, such as an LCD screen, an LED display, an OLED display, an electrophoretic display, a computer monitor, a touchscreen, a television, etc., one or more speakers, and so on.

In some embodiments, communications systems 826 can include any suitable hardware, firmware, and/or software for communicating information to computing device 750 (and, in some embodiments, over communication network 754 and/or any other suitable communication networks). For example, communications systems 826 can include one or more transceivers, one or more communication chips and/or chip sets, and so on. In a more particular example, communications systems 826 can include hardware, firmware, and/or software that can be used to establish a wired connection using any suitable port and/or communication standard (e.g., VGA, DVI video, USB, RS-232, etc.), Wi-Fi connection, a Bluetooth connection, a cellular connection, an Ethernet connection, and so on.

In some embodiments, memory 828 can include any suitable storage device or devices that can be used to store instructions, values, data, or the like, that can be used, for example, by processor 822 to control the one or more data acquisition systems 824, and/or receive data from the one or more data acquisition systems 824; to generate images from data; present content (e.g., images, a user interface) using a display; communicate with one or more computing devices 750; and so on. Memory 828 can include any suitable volatile memory, non-volatile memory, storage, or any suitable combination thereof. For example, memory 828 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some embodiments, memory 828 can have encoded thereon, or otherwise stored therein, a program for controlling operation of data source 802. In such embodiments, processor 822 can execute at least a portion of the program to generate images, transmit information and/or content (e.g., data, images) to one or more computing devices 750, receive information and/or content from one or more computing devices 750, receive instructions from one or more devices (e.g., a personal computer, a laptop computer, a tablet computer, a smartphone, etc.), and so on.

In some embodiments, any suitable computer-readable media can be used for storing instructions for performing the functions and/or processes described herein. For example, in some embodiments, computer-readable media can be transitory or non-transitory. For example, non-transitory computer-readable media can include media such as magnetic media (e.g., hard disks, floppy disks), optical media (e.g., compact discs, digital video discs, Blu-ray discs), semiconductor media (e.g., RAM, flash memory, EPROM, EEPROM), any suitable media that is not fleeting or devoid of any semblance of permanence during transmission, and/or any suitable tangible media. As another example, transitory computer-readable media can include signals on networks, in wires, conductors, optical fibers, circuits, or any suitable media that is fleeting and devoid of any semblance of permanence during transmission, and/or any suitable intangible media.

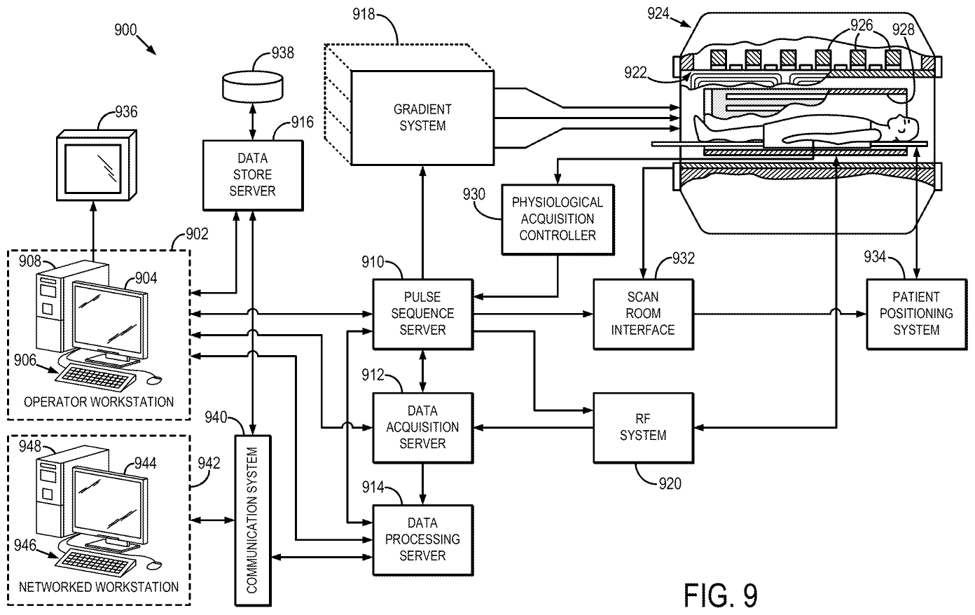

Referring particularly now to FIG. 9, an example of an MRI system 900 that can implement the methods described here is illustrated. The MRI system 900 includes an operator workstation 902 that may include a display 904, one or more input devices 906 (e.g., a keyboard, a mouse), and a processor 908. The processor 908 may include a commercially available programmable machine running a commercially available operating system. The operator workstation 902 provides an operator interface that facilitates entering scan parameters into the MRI system 900. The operator workstation 902 may be coupled to different servers, including, for example, a pulse sequence server 910, a data acquisition server 912, a data processing server 914, and a data store server 916. The operator workstation 902 and the servers 910, 912, 914, and 916 may be connected via a communication system 940, which may include wired or wireless network connections.

The pulse sequence server 910 functions in response to instructions provided by the operator workstation 902 to operate a gradient system 918 and a radiofrequency (“RF”) system 920. Gradient waveforms for performing a prescribed scan are produced and applied to the gradient system 918, which then excites gradient coils in an assembly 922 to produce the magnetic field gradients Gₓ, G_{y}, and G_{z} that are used for spatially encoding magnetic resonance signals. The gradient coil assembly 922 forms part of a magnet assembly 924 that includes a polarizing magnet 926 and a whole-body RF coil 928.

RF waveforms are applied by the RF system 920 to the RF coil 928, or a separate local coil to perform the prescribed magnetic resonance pulse sequence. Responsive magnetic resonance signals detected by the RF coil 928, or a separate local coil, are received by the RF system 920. The responsive magnetic resonance signals may be amplified, demodulated, filtered, and digitized under direction of commands produced by the pulse sequence server 910. The RF system 920 includes an RF transmitter for producing a wide variety of RF pulses used in MRI pulse sequences. The RF transmitter is responsive to the prescribed scan and direction from the pulse sequence server 910 to produce RF pulses of the desired frequency, phase, and pulse amplitude waveform. The generated RF pulses may be applied to the whole-body RF coil 928 or to one or more local coils or coil arrays.

The RF system 920 also includes one or more RF receiver channels. An RF receiver channel includes an RF preamplifier that amplifies the magnetic resonance signal received by the coil 928 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

$$M = \sqrt{{I}^{2} + {Q}^{2}} ;$$

and the phase of the received magnetic resonance signal may also be determined according to the following relationship:

$$φ = {tan}^{- 1} ( \frac{Q}{I} ) .$$

The pulse sequence server 910 may receive patient data from a physiological acquisition controller 930. By way of example, the physiological acquisition controller 930 may receive signals from a number of different sensors connected to the patient, including electrocardiograph (“ECG”) signals from electrodes, or respiratory signals from a respiratory bellows or other respiratory monitoring devices. These signals may be used by the pulse sequence server 910 to synchronize, or “gate,” the performance of the scan with the subject's heart beat or respiration.

The pulse sequence server 910 may also connect to a scan room interface circuit 932 that receives signals from various sensors associated with the condition of the patient and the magnet system. Through the scan room interface circuit 932, a patient positioning system 934 can receive commands to move the patient to desired positions during the scan.

The digitized magnetic resonance signal samples produced by the RF system 920 are received by the data acquisition server 912. The data acquisition server 912 operates in response to instructions downloaded from the operator workstation 902 to receive the real-time magnetic resonance data and provide buffer storage, so that data is not lost by data overrun. In some scans, the data acquisition server 912 passes the acquired magnetic resonance data to the data processor server 914. In scans that require information derived from acquired magnetic resonance data to control the further performance of the scan, the data acquisition server 912 may be programmed to produce such information and convey it to the pulse sequence server 910. For example, during pre-scans, magnetic resonance data may be acquired and used to calibrate the pulse sequence performed by the pulse sequence server 910. As another example, navigator signals may be acquired and used to adjust the operating parameters of the RF system 920 or the gradient system 918, or to control the view order in which k-space is sampled. In still another example, the data acquisition server 912 may also process magnetic resonance signals used to detect the arrival of a contrast agent in a magnetic resonance angiography (“MRA”) scan. For example, the data acquisition server 912 may acquire magnetic resonance data and processes it in real-time to produce information that is used to control the scan.

The data processing server 914 receives magnetic resonance data from the data acquisition server 912 and processes the magnetic resonance data in accordance with instructions provided by the operator workstation 902. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, generating functional magnetic resonance images, or calculating motion or flow images.

Images reconstructed by the data processing server 914 are conveyed back to the operator workstation 902 for storage. Real-time images may be stored in a data base memory cache, from which they may be output to operator display 902 or a display 936. Batch mode images or selected real time images may be stored in a host database on disc storage 938. When such images have been reconstructed and transferred to storage, the data processing server 914 may notify the data store server 916 on the operator workstation 902. The operator workstation 902 may be used by an operator to archive the images, produce films, or send the images via a network to other facilities.

The MRI system 900 may also include one or more networked workstations 942. For example, a networked workstation 942 may include a display 944, one or more input devices 946 (e.g., a keyboard, a mouse), and a processor 948. The networked workstation 942 may be located within the same facility as the operator workstation 902, or in a different facility, such as a different healthcare institution or clinic.

The networked workstation 942 may gain remote access to the data processing server 914 or data store server 916 via the communication system 940. Accordingly, multiple networked workstations 942 may have access to the data processing server 914 and the data store server 916. In this manner, magnetic resonance data, reconstructed images, or other data may be exchanged between the data processing server 914 or the data store server 916 and the networked workstations 942, such that the data or images may be remotely processed by a networked workstation 942.

The present disclosure has described one or more preferred embodiments, and it should be appreciated that many equivalents, alternatives, variations, and modifications, aside from those expressly stated, are possible and within the scope of the invention.

1. A method for reconstructing denoised magnetic resonance images, the method comprising:
(a) accessing k-space data with a computer system, wherein the k-space data have been acquired using a multichannel receiver;
(b) reconstructing coil channel images from the k-space data using the computer system, wherein each coil channel image corresponds to a different channel of the multichannel receiver;
(c) generating denoised coil channel images with the computer system by applying a denoising algorithm to the coil channel images using the computer system;
(d) generating denoised k-space data from the denoised coil channel images using the computer system to transform the denoised coil channel images into k-space; and
(e) reconstructing denoised magnetic resonance images from the denoised k-space data using the computer system by applying the denoised k-space data to a nonlinear reconstruction algorithm, generating output as the denoised magnetic resonance images.

2. The method of claim 1, wherein reconstructing the denoised magnetic resonance images comprises:
accessing a neural network with the computer system, wherein the neural network has been trained on training data to reconstruct magnetic resonance images from k-space data based on a nonlinear image reconstruction framework; and
applying the denoised k-space data to the neural network, generating output as the denoised magnetic resonance images.

3. The method of claim 2, wherein the nonlinear image reconstruction framework includes a physics-guided deep learning image reconstruction.

4. The method of claim 2, wherein the neural network has been trained on training data using self-supervised learning.

5. The method of claim 4, wherein the neural network has been trained on training data by separating the training data into a first subset of training data and a second subset of training data, wherein the first subset of training data is used within the neural network during training and the second subset of training data is used in a loss function used during training.

6. The method of claim 5, wherein the first subset of training data defines data consistency units and the second subset of training data defined k-space loss.

7. The method of claim 2, wherein the k-space data have been acquired from a subject and the training data comprise subject-specific training data also acquired from the subject.

8. The method of claim 1, wherein the denoising algorithm comprises a locally low-rank (LLR)-based denoising algorithm.

9. The method of claim 8, wherein the LLR-based denoising algorithm comprises:
selecting, with the computer system, an image patch corresponding to the coil channel images;
forming a matrix with the computer system by combining vectors generated using the image patch; and
applying a locally low-rank denoising with the computer system using the matrix and the coil channel images to generate the denoised coil channel images.

10. The method of claim 9, wherein the locally low-rank denoising implements a singular value decomposition.

11. The method of claim 10, wherein the locally low-rank denoising implements a singular value thresholding.

12. The method of claim 11, wherein the singular value thresholding is implemented using a threshold value computed based on singular values of a random Gaussian matrix.

13. The method of claim 1, wherein the denoising algorithm is a channel-independent denoising algorithm.

14. The method of claim 1, wherein the denoising algorithm comprises a neural network that has been trained on training data to denoise an input image, wherein generating the denoised coil channel images with the computer system comprises inputting the coil channel imaged to the neural network, generating the denoised coil channel images as an output.

15. The method of claim 14, wherein the neural network is a convolutional neural network.

16. The method of claim 1, wherein the k-space data accessed with the computer system comprise undersampled k-space data.

17. The method of claim 1, wherein the coil channel images comprise a dynamic series of images.

18. The method of claim 1, wherein the coil channel images comprise a contrast-varying series of images.

19. A method for reconstructing denoised magnetic resonance images, the method comprising:
(a) accessing k-space data with a computer system, wherein the k-space data have been acquired using a multichannel receiver;
(b) reconstructing coil channel images from the k-space data using the computer system, wherein each coil channel image corresponds to a different channel of the multichannel receiver;
(c) generating denoised coil channel images with the computer system by applying a singular value thresholding using a locally low-rank (LLR) model to the coil channel images using the computer system;
(d) generating denoised k-space data from the denoised coil channel images using the computer system to transform the denoised coil channel images into k-space; and
(e) reconstructing denoised magnetic resonance images from the denoised k-space data using the computer system.

20. The method of claim 19, wherein the denoised magnetic resonance images are reconstructed from the denoised k-space data using a nonlinear reconstruction algorithm.

21. The method of claim 19, wherein the k-space data are undersampled k-space data, and the coil channel images contain aliasing artifacts.

22. The method of claim 21, wherein the LLR model is based on a subadditivity of matrix rank for aliased image patches in the coil channel images.

23. A method for reconstructing denoised magnetic resonance images, the method comprising:
(a) accessing k-space data with a computer system;
(b) generating denoised k-space data with the computer system by applying a singular value thresholding using a locally low-rank (LLR) model to the k-space data using the computer system; and
(c) reconstructing denoised magnetic resonance images from the denoised k-space data using the computer system.

24. The method of claim 23, wherein the denoised magnetic resonance images are reconstructed from the denoised k-space data using a nonlinear reconstruction algorithm.

25. The method of claim 24, wherein reconstructing the denoised magnetic resonance images comprises:
accessing a neural network with the computer system, wherein the neural network has been trained on training data to reconstruct magnetic resonance images from k-space data based on a nonlinear image reconstruction framework; and
applying the denoised k-space data to the neural network, generating output as the denoised magnetic resonance images.
